(19) United States
(12) Patent Application Publication
(10) Pub. No.: US 2010/0116208 A1
(43) Pub. Date: May 13, 2010

(54) AMPOULE AND DELIVERY SYSTEM FOR SOLID PRECURSORS

(75) Inventor: KEDARNATH S. SANGAM, Sunnyvale, CA (US)

Correspondence Address: MOSER IP LAW GROUP / APPLIED MATERIALS, INC., 1030 BROAD STREET, 2ND FLOOR, SHREWSBURY, NJ, 07702, US

(73) Assignee: APPLIED MATERIALS, INC., Santa Clara, CA (US)

(21) Appl. No.: 12/270,656

(22) Filed: Nov. 13, 2008

(51) Int. Cl. C23C 16/54

(52) U.S. Cl. 118/723 MW; 118/715; 118/723 R

(57) ABSTRACT

Gas delivery systems for delivering gaseous precursors sublimated from solid form are disclosed herein. In some embodiments, the gas delivery system may include an ampoule to hold a solid precursor that can sublimate to a gaseous form within the ampoule; and a carrier gas line coupled to the ampoule at a junction disposed in the carrier gas line, wherein the carrier gas line has a first cross-sectional area proximate an inlet and an outlet of the junction and a smaller, second cross-sectional area within the junction, and wherein a carrier gas flowing through the junction creates a pressure within in the junction that is less than a pressure within the ampoule.

### FIELD

Embodiments of the present invention generally relate to semiconductor process equipment and more particularly to a gas delivery system for delivering a precursor to a process chamber.

### BACKGROUND

During substrate processing, a gas delivery system may be utilized to deliver a precursor to a process chamber. In some embodiments, the precursor may be a molecule having a low vapor pressure, for example, hafnium tetrachloride (HfCl₄), that is stored, in solid form, in an ampoule coupled to the gas delivery system. To deliver such a precursor to the process chamber, the precursor is first sublimed into a gaseous form. Next, the gaseous precursor is delivered to the process chamber using a carrier gas that flows through the ampoule, mixes with the gaseous precursor, and continues to the process chamber.

The sublimation of the precursor may be enabled by supplying heat to the walls of the ampoule. For example, the exterior surface of the ampoule can be covered with external heaters, heating pads, or the like. Unfortunately, and partially due to the cylindrical shape of conventional ampoules, heat transfer to the precursor is inefficient. For example, the low surface to volume ratio of a cylindrical ampoule can result in sublimed precursor proximate the walls of the ampoule, while precursor disposed centrally within the ampoule remains in solid form. Moreover, particularly when using solid precursors with a high enthalpy of sublimation (e.g., 100,000 kJ/mole for HfCl₄), inefficient heating of the solid precursor combined with the loss of heat to neighboring particles of the precursor leads to slow reaction time to develop sufficient quantities of gaseous precursor. In addition, the ampoule may be configured such that the carrier gas flows through the ampoule. Thus, portions of the remaining solid precursor can be swept up by the carrier gas, and deposited in the gas delivery lines or in the process chamber. As a result, gas delivery lines can be clogged and particulate matter can be deposited in the process chamber.

Accordingly, there is a need in the art for an improved gas delivery system.

### SUMMARY

Gas delivery systems for delivering gaseous precursors sublimated from solid form are disclosed herein. In some embodiments, the gas delivery system may include an ampoule to hold a solid precursor that can sublimate to a gaseous form within the ampoule; and a carrier gas line coupled to the ampoule at a junction disposed in the carrier gas line, wherein the carrier gas line has a first cross-sectional area proximate an inlet and an outlet of the junction and a smaller, second cross-sectional area within the junction, and wherein a carrier gas flowing through the junction creates a pressure within in the junction that is less than a pressure within the ampoule.

In some embodiments, a semiconductor processing system may include a process chamber having an internal processing volume; and a gas delivery system. The gas delivery system may include an ampoule to hold a solid precursor that can sublimate to a gaseous form within the ampoule; a carrier gas line coupled to the ampoule at a junction disposed in the carrier gas line, wherein the carrier gas line has a first cross-sectional area proximate an inlet and an outlet of the junction and a smaller, second cross-sectional area within the junction, and wherein a carrier gas flowing through the junction creates a pressure within in the junction that is less than a pressure within the ampoule; and a carrier gas source coupled to the carrier gas line.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic cross-sectional view of a process chamber in accordance with some embodiments of the present invention.

FIGS. 2A-B respectively depict schematic front and side views of a gas delivery system in accordance with some embodiments of the present invention.

FIG. 3 is a schematic front view of a gas delivery assembly in accordance with some embodiments of the present invention.

To facilitate understanding, identical reference numerals have been used, where possible, to designate identical elements that are common to the figures. The above drawings are not to scale and may be simplified for illustrative purposes.

### DETAILED DESCRIPTION

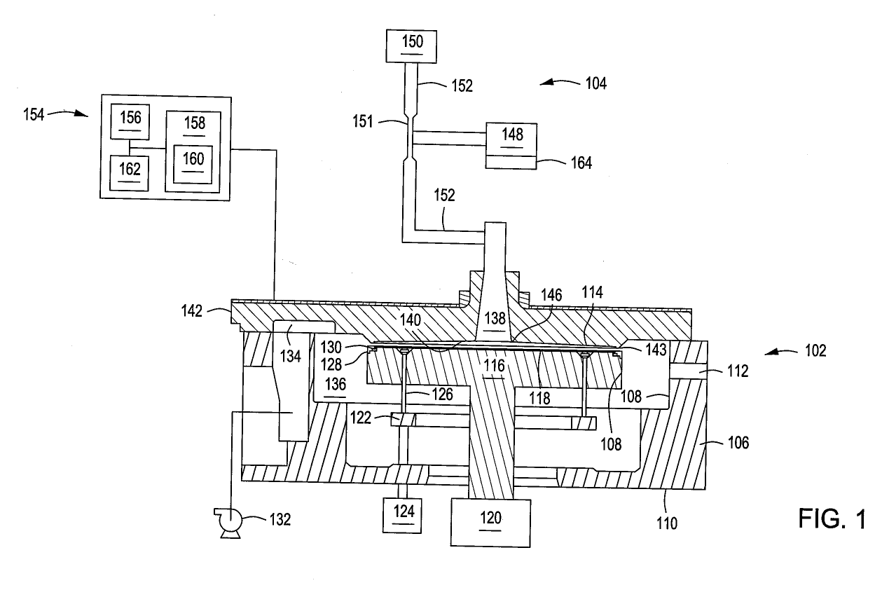

A gas delivery system is disclosed herein, and may be utilized to deliver low vapor pressure precursors, such as hafnium tetrachloride (HfCl₄) to a process chamber. The gas delivery system includes an ampoule for holding a precursor in solid form and a carrier gas line coupled to the ampoule at a junction disposed in the carrier gas line. The gas delivery system advantageously improves heat transfer to the ampoule by providing an ampoule having a high surface to volume ratio, and/or additional heating mechanisms, such as a radiant energy source. Further, the design of the junction facilitates drawing the gaseous precursor out of the ampoule without the carrier gas entering the ampoule, thus advantageously reducing or eliminating any un-sublimed precursor from entering the carrier gas line. The gas delivery system of the present invention may be coupled to a process chamber configured for cyclical deposition. One such exemplary process chamber is described in FIG. 1.

FIG. 1 is a schematic cross-sectional view of an exemplary process chamber 102 including a gas delivery system 104 adapted for cyclic deposition, such as Atomic Layer Deposition or Rapid Chemical Vapor Deposition. The terms Atomic Layer Deposition (ALD) and Rapid Chemical Vapor Deposition as used herein refer to the sequential introduction of the reactant gas to deposit a thin layer over the substrate structure. The sequential introduction of the reactant gas may be repeated to deposit a plurality of thin layers to form a conformal layer to a desired thickness. The process chamber 102 may also be adapted for other deposition techniques.

The process chamber 102 includes a chamber body 106 having sidewalls 108 and a bottom 110. A slit valve 112 in the process chamber 102 provides access for a robot (not shown) to deliver and retrieve a substrate 114, such as a semiconductor wafer with a diameter of 200 mm or 300 mm or a glass substrate, from the process chamber 102. The process chamber 102 may be various types of ALD chambers. The details of the exemplary process chamber 102 are described in commonly assigned United States Patent Application Publication No. 2005-0271813, filed on May 12, 2005, entitled “Apparatuses and Methods for Atomic Layer Deposition of Hafnium-Containing High-K Dielectric Materials,” and United States Patent Application Publication No. 20030079686, filed on Dec. 21, 2001, entitled “Gas Delivery Apparatus and Method For Atomic Layer Deposition”, which are both incorporated herein in their entirety by references. Two exemplary chambers suitable for use with the inventive gas delivery system may include GEMINI™ ALD or CVD chambers available from Applied Materials, Inc.

A substrate support 116 supports the substrate 114 on a substrate receiving surface 118 in the process chamber 102. The substrate support (or pedestal) 116 is mounted to a lift motor 120 to raise and lower the substrate support 116 and the substrate 114 disposed thereon. A lift plate 122 connected to a lift motor 124 is mounted in the process chamber 102 and raises and lowers pins 126 movably disposed through the substrate support 116. The pins 126 raise and lower the substrate 114 over the surface of the substrate support 116. In some embodiments, the substrate support 116 may include a vacuum chuck, an electrostatic chuck, or a clamp ring for securing the substrate 114 to the substrate support 116 during processing.

The substrate support 116 may be heated to increase the temperature of the substrate 114 disposed thereon. For example, the substrate support 116 may be heated using an embedded heating element, such as a resistive heater, or may be heated using radiant heat, such as heating lamps disposed above the substrate support 116. A purge ring 128 may be disposed on the substrate support 116 to define a purge channel 130 which provides a purge gas to a peripheral portion of the substrate 114 to prevent deposition thereon.

The gas delivery system 104 may be disposed in any suitable location, such as an upper portion of the chamber body 106, to provide one or more gases, such as a reactant gas (e.g., a precursor) and/or a purge gas, to the process chamber 102. A vacuum system 132 is in communication with a pumping channel 134 to evacuate any desired gases from the process chamber 102 and to help maintain a desired pressure or a desired pressure range inside a pumping zone 136 of the process chamber 102.

The gas delivery system 104 includes an ampoule 148 coupled to a carrier gas line 152 having a junction 151 disposed therein. The ampoule 148 is configured for storing and vaporizing a solid precursor therein and is coupled to the carrier gas line 152 at the junction 151. In some embodiments, the precursor can be a low vapor pressure precursor. In some embodiments, the precursor can be hafnium tetrachloride (HfCl₄) or the like. The precursor in the ampoule 148 may be sublimated from solid to gaseous form by, for example, heating the precursor. The ampoule may be fabricated from process-compatible materials suitable for holding the precursor and for transferring energy to the precursor. For example, the ampoule may by fabricated, at least in part, from highly heat conductive materials, such as stainless steel, aluminum, or the like, or from materials transparent to radiant energy provided to the precursor, such as quartz, or the like.

Upon sublimation, the gaseous precursor is ready to be transported to the process chamber via a carrier gas flowing through the carrier gas line 152. In some embodiments, the carrier gas line 152 (or portions thereof may be heated to a temperature higher than ambient and above the sublimation temperature to prevent or limit condensation of any of the sublimed gases in the carrier gas line 152.

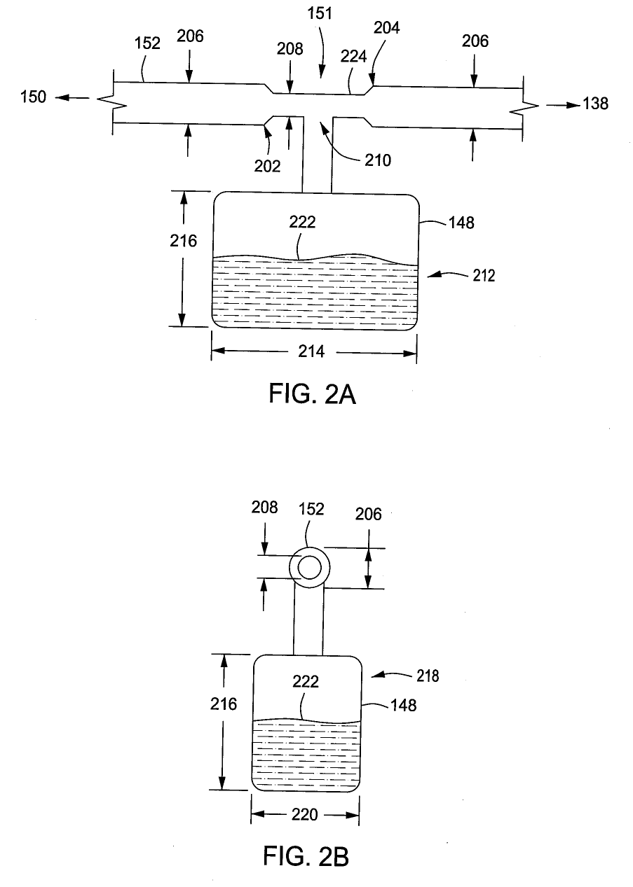

The ampoule may have a geometry configured to improve the efficiency of the energy transfer to the precursor contained within the ampoule. In one non-limiting embodiment, the ampoule 148 may have a generally rectangular shape as depicted in FIGS. 2A-B. As depicted in the front view of FIG. 2A, the ampoule 148 may have a first rectangular cross-section 212 defined by a length 214 and height 216 of the ampoule 148. The ampoule 148 further includes a second rectangular cross-section 218 defined by the height 216 and a width 220 of the ampoule 148 as depicted in side view in FIG. 2B. Thus, in this one non-limiting embodiment, the ampoule 148 has a rectangular cross-section on each side of the ampoule 148. In some embodiments, a ratio of the first rectangular cross-section to the second rectangular cross-section of the ampoule is between about 3 or higher. This exemplary configuration of the ampoule 148 facilitates providing a high surface area to volume ratio of the ampoule 148. However, the ampoule 148 is not limited to a rectangular cross-section, and may include any suitable cross-section and/or shape.

The dimensions of the ampoule 148 (i.e. length 214, height 216 and width 220) may be selected to provide a high surface area to volume ratio. In some embodiments, the surface to volume ratio is about 0.4 or more. For example, an ampoule with a volume of 1 liter (or 1000 cc) having a cylindrical shape (e.g., a regular cylinder with a circular cross-section) and a height of 10 cm, has a surface area (vertical wall) to volume ratio of approximately 0.36. In comparison, an ampoule of the same size (1000 cc) but having a rectangular cross-section (for example, 3 cm×20 cm and a height of 16 cm) has a surface area (vertical walls) to volume ratio of about 0.64. Larger values of this measure indicate better heat transfer ability from an external heat source to the precursor material inside the ampoule. A high surface area to volume ratio may facilitate improved sublimation of a precursor 222 disposed in the ampoule 148 when heat is supplied to the ampoule surface. In some embodiments, one or more heating elements (not shown) may be coupled to an exterior of the ampoule 148 to facilitate the heating thereof. The heating elements may comprise heating pads, or the like, and may cover some or the entire exterior surface of the ampoule 148. In some embodiments, the precursor 222 may be mixed, stirred, or agitated to maximize the exposure of the precursor 222 to heat from the heating elements. The precursor 222 may be mixed by providing an agitator (e.g., agitator 164 depicted in FIG. 1) such as a magnetic stirring agitator, a vibrator, or other suitable agitating mechanism. The agitator may be used for mixing, stirring, agitating, or the like.

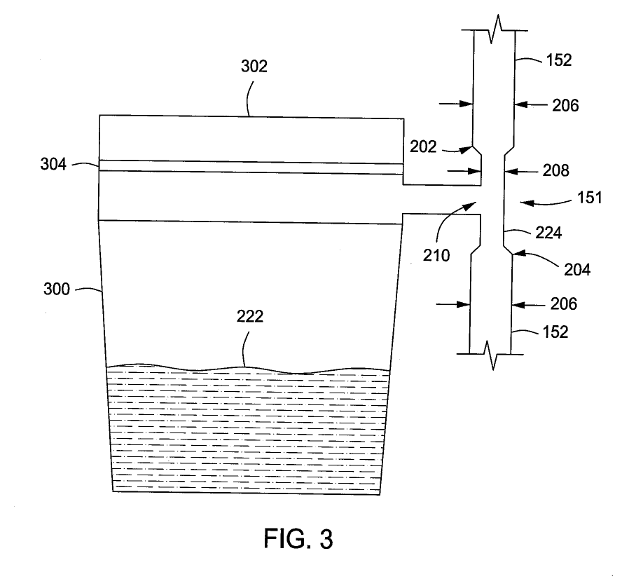

In some embodiments, as depicted in FIG. 3, a radiant energy source may be alternatively or in combination coupled to the ampoule to provide sufficient energy to sublimate the precursor 222. FIG. 3 is a schematic front view of portions of a gas delivery assembly including an ampoule 300 coupled to the carrier gas line 152 at the opening 210 of the junction 151. The ampoule 300 may be of any suitable shape as described above with respect to the ampoule 148. As depicted in a non-limiting embodiment in FIG. 3, the ampoule 300 has a trapezoidal cross-section. In some embodiments, the shape of the ampoule 300 may be selected to maximize expose of the precursor 222 to a radiant energy source 302 coupled to the ampoule 300. The radiant energy source 302 may be illustratively disposed above the ampoule 300, and capable of transmitting radiant energy through a material that forms at least a portion the ampoule 300 (for example, a top portion as shown in FIG. 3). For example, in some embodiments, the radiant energy source 302 is coupled to the ampoule 300 via a window 304. The window 304 may comprise any suitable material for transmitting the radiant energy to the precursor 222. In some embodiments, the window 304 comprises quartz.

The radiant energy source 302 may include any suitable source for providing energy to the precursor disposed in the ampoule, such as an ultraviolet radiation source, an infrared radiation source, a microwave radiation source, a halogen lamp, a laser, or the like. The radiant energy source may provide radiant energy at any suitable wavelength necessary to sublimate the precursor 222. In some embodiments, the wavelength of radiant energy may include at least one of ultraviolet, infrared, microwave, and the like.

In some embodiments, heating elements (not shown) may be further coupled to an exterior surface of the ampoule 300 as described above. The heating elements may provide additional energy for subliming the precursor 222. Further, the precursor 222 may be mixed, stirred, or agitated to maximize the exposure of the precursor 222 to the radiant energy of the radiant energy source 302, and when heating elements are provided, maximize exposure of the precursor 222 to the walls of the ampoule 300.

Returning to FIG. 1, a carrier gas source 150 is coupled to the carrier gas line 152 for providing the carrier gas. In some embodiments, the carrier gas may include at least one of nitrogen, helium, argon, or the like. As discussed below with respect to FIGS. 2A-B, the junction 151 and the gas delivery line 152 are configured to draw the gaseous precursor from the ampoule 148 when the carrier gas flows through the gas delivery line 152 and the junction 151, thereby forming a gaseous mixture which may be delivered to the process chamber 102.

FIG. 2A depicts a front view of a portion of the gas delivery system 104 including the ampoule 148, carrier gas line 152 and the junction 151 in accordance with some embodiments of the present invention. The gas delivery line 152 has a first diameter, or cross-sectional area 206 on either side of the junction 151. As depicted in the FIG. 2A, the junction 151 is disposed inline within the carrier gas line 152 and includes a conduit 224 having a diameter, or cross-sectional area 208, that is smaller than the cross sectional area 206 of the carrier gas line 152. The conduit 224 includes a inlet 202 and an outlet 204 for facilitating the flow of a carrier gas therethrough. To facilitate smooth flow transition between the carrier gas line 152 and the junction 151, a portion of the carrier gas line 152 proximate the inlet 202 may taper from the first cross-sectional area 206 down to the second cross-sectional area 208 of the junction 151. Similarly, a portion of the carrier gas line 152 proximate the outlet 204 may taper upwards from the second cross-sectional area 208 to the first cross-sectional area 206. Although as shown as having the same cross sectional area 206, it is contemplated that the carrier gas line 152 may have different cross-sectional areas on either side of the junction 151, provided that both are larger than the cross-sectional area of the junction 151.

The junction 151 further comprises an opening 210 for coupling the junction 151 to the ampoule 148. The opening 210 may include elements for coupling to ampoules made of dissimilar materials than the junction 151. For example, in embodiments where the ampoule 148 is made of quartz, the opening 210 may comprise a metal-to-glass joint, for example, such as stainless steel on the junction side of the opening 210 and quartz on the ampoule side of the opening 210.

Returning to FIG. 1, the gas delivery system 104 may further comprise a chamber lid 142. The chamber lid 142 can include a gas inlet funnel 138 extending from a central portion of the chamber lid 142 and a bottom surface 140 extending from the gas inlet funnel 138 to a peripheral portion of the chamber lid 142. The bottom surface 140 is sized and shaped to substantially cover the substrate 114 disposed on the substrate support 116. The chamber lid 142 may have a choke 143 at a peripheral portion of the chamber lid 142 adjacent the periphery of the substrate 114. The carrier gas line 152 is coupled to the gas inlet funnel 138 at a gas inlet 139.

A portion of bottom surface 140 of a chamber lid 142 may be tapered from the gas inlet funnel 138 to a peripheral portion of the chamber lid 142 to help provide an improved velocity profile of a gas flow from the expanding channel 138 across the surface of the substrate 114 (e.g., from the center of the substrate to the edge of the substrate). The bottom surface 140 may include one or more tapered surfaces, such as a straight surface, a concave surface, a convex surface, or combinations thereof. In one embodiment, the bottom surface 140 is tapered in the shape of a funnel.

The gas inlet funnel 138 and gas delivery system 104 are depicted herein for ease of understanding. For example, the gas inlet funnel 138 may have multiple gas inlets (not shown) for receiving carrier gases, process gases, gaseous mixtures, or the like. Further, the gas delivery system 104 may further comprise multiple gas sources (not shown) coupled to inlets of the gas inlet funnel 138 through multiple gas lines (not shown). Gases from the multiple sources may be mixed prior to entering an inlet of the gas inlet funnel 138, and/or flow rates of gases may be controlled by valves, mass flow controllers or the like.

A control unit 154, such as a programmed personal computer, work station computer, or the like, may be coupled to the process chamber 680 to control processing conditions. For example, the control unit 154 may be configured to control supplying energy to an ampoule for subliming a precursor and the flow of a carrier gas during different stages of a substrate process sequence. Illustratively, the control unit 154 includes a Central Processing Unit (CPU) 156, support circuitry 162, and a memory 158 having associated control software 160.

In operation, and referring to FIGS. 1-3, the precursor 222 is heated to form a vapor of the precursor 222 within the ampoule 148 (or ampoule 300). For example, the temperature of a precursor such as hafnium tetrachloride (HfCl₄) may be maintained above a critical temperature (about 135 degrees Celsius for HfCl₄) thereby sublimating a portion of the precursor 222 and forming a vapor pressure in the ampoule of, for example, about 0.1 Torr. A carrier gas is flowed from the carrier gas source 150 through the carrier gas line 152 having the first cross-sectional area 206. The carrier gas enters the inlet 202 of the junction 151, where the cross sectional area of the carrier gas line tapers down to the second cross sectional area 208 with the junction. As a result of the reduction in cross sectional area, the velocity of the carrier gas increases and the pressure decreases within the junction 151. The reduced pressure within the junction 151 is less than the vapor pressure of the precursor within the ampoule 148 (or ampoule 300). Thus, the vapor of precursor 222 flows out of the ampoule 148 and into the junction 151 where the vapor mixes with the carrier gas flowing through the junction 151. The gaseous mixture exits the junction 151 at the outlet 204, and proceeds through the carrier gas line 152 to the gas inlet funnel 138 where the gaseous mixture enters the process chamber 102.

Thus, an improved gas delivery system is disclosed herein. The gas delivery system may be utilized to delivery low vapor pressure precursors, such as hafnium tetrachloride (HfCl₄) to a process chamber. The gas delivery system advantageously improves heat transfer to the ampoule by providing an ampoule having a high surface to volume ratio, and/or by supplying additional heating mechanisms, such as a radiant energy source. Further, the gas delivery system facilitates delivering precursors to the process chamber without the carrier gas entering the ampoule, thus advantageously preventing or restricting any un-sublimed precursor from entering the carrier gas line.

While the foregoing is directed to embodiments of the present invention, other and further embodiments of the invention may be devised without departing from the basic scope thereof.

1. A gas delivery system, comprising:
an ampoule to hold a solid precursor that can sublimate to a gaseous form within the ampoule; and
a carrier gas line coupled to the ampoule at a junction disposed in the carrier gas line, wherein the carrier gas line has a first cross-sectional area proximate an inlet and an outlet of the junction and a smaller, second cross-sectional area within the junction, and wherein a carrier gas flowing through the junction creates a pressure within in the junction that is less than a pressure within the ampoule.

2. The gas delivery system of claim 1, wherein the ampoule is fabricated from at least one of quartz, stainless steel, or aluminum.

3. The gas delivery system of claim 1, wherein the ampoule has a first rectangular cross-section defined by a length and height of the ampoule and a second rectangular cross-section defined by the height and a width of the ampoule.

4. The gas delivery system of claim 3, wherein a ratio of the first rectangular cross-section to the second rectangular cross-section of the ampoule is about 3 or greater.

5. The gas delivery system of claim 1, wherein a ratio between surface area to volume of the ampoule is about 0.4 or greater.

6. The gas delivery system of claim 1, wherein one or more heating elements are coupled to an exterior surface of the ampoule.

7. The gas delivery system of claim 6, further comprising:
an agitator coupled to the ampoule to agitate a precursor disposed within the ampoule.

8. The gas delivery system of claim 1, further comprising:
a radiant energy source coupled to the ampoule to provide radiant energy to facilitate sublimation of the precursor.

9. The gas delivery system of claim 8, wherein a wavelength of radiant energy provided by the radiant energy source includes at least one of ultraviolet, visible, infrared, or microwave.

10. The gas delivery system of claim 8, wherein the radiant energy source includes at least one of an ultraviolet radiation source, a infrared radiation source, a microwave radiation source, a halogen lamp, or a laser.

11. The gas delivery system of claim 8, wherein the ampoule further comprises:
a window transparent to radiant energy disposed between the ampoule and the radiant energy source.

12. The gas delivery system of claim 11, wherein the window comprises quartz.

13. The gas delivery system of claim 8, wherein the ampoule has a decreasing cross-sectional area along an axis normal to the radiant energy source in a direction moving away from the radiant energy source.

14. The gas delivery system of claim 8, further comprising:
an agitator coupled to the ampoule to agitate a precursor disposed within the ampoule.

15. A semiconductor processing system, comprising:
a process chamber having an internal processing volume; and
a gas delivery system, comprising:
an ampoule to hold a solid precursor that can sublimate to a gaseous form within the ampoule;
a carrier gas line coupled to the ampoule at a junction disposed in the carrier gas line, wherein the carrier gas line has a first cross-sectional area proximate an inlet and an outlet of the junction and a smaller, second cross-sectional area within the junction, and wherein a carrier gas flowing through the junction creates a pressure within in the junction that is less than a pressure within the ampoule; and
a carrier gas source coupled to the carrier gas line.

16. The system of claim 15, wherein the ampoule has a first rectangular cross-section defined by a length and height of the ampoule and a second rectangular cross-section defined by the height and a width of the ampoule and wherein one or more heating elements are coupled to an exterior surface of the ampoule.

17. The system of claim 15, further comprising:
a radiant energy source coupled to the ampoule to provide radiant energy to facilitate sublimation of the precursor.

18. The system of claim 15, further comprising:
an agitator coupled to the ampoule to agitate a precursor disposed within the ampoule.
